(19) United States
(12) Patent Application Publication
(10) Pub. No.: US 2010/0118905 A1
(43) Pub. Date: May 13, 2010

(54) NITRIDE SEMICONDUCTOR LASER DIODE AND MANUFACTURING METHOD THEREOF

(76) Inventors: Tomohito YABUSHITA, Hyogo (JP); Yasutoshi Kawaguchi, Hyogo (JP); Akio Ueta, Hyogo (JP); Akihiko Ishibashi, Hyogo (JP)

Correspondence Address: MCDERMOTT WILL & EMERY LLP, 600 13TH STREET, NW, WASHINGTON, DC, 20005-3096, US

(21) Appl. No.: 12/547,906

(22) Filed: Aug. 26, 2009

(30) Foreign Application Priority Data
Nov. 7, 2008 (JP) 2008-286309
Jun. 17, 2009 (JP) 2009-144143

(51) Int. Cl. H01S 5/00; H01L 33/00

(52) U.S. Cl. 372/45.01; 438/46; 257/E33.028

(57) ABSTRACT

A nitride semiconductor laser diode includes a substrate of n-type GaN, and a multilayer structure including an n-type cladding layer of AlₓGa₁₋ₓ N (where 0<x<1) formed on and in contact with a main surface of the substrate, an MQW active layer formed on the n-type cladding layer, and a p-type cladding layer formed on the MQW active layer. The main surface of the substrate is oriented at an angle ranging from 0.25° to 0.7° with respect to a (0001) plane of a plane orientation. The composition x of the AlₓGa₁₋ₓN is in a range from 0.025 to 0.04.

### CROSS-REFERENCE TO RELATED APPLICATIONS

This application claims priority to Japanese Patent Application No. 2008-286309 filed on Nov. 7, 2008 and No. 2009-144143 filed on Jun. 17, 2009, the disclosures of which including the specifications, the drawings, and the claims are hereby incorporated by reference in their entirety.

### BACKGROUND

The present disclosure relates to semiconductor laser diodes including nitride semiconductors formed on substrates of nitride gallium (GaN), and manufacturing methods thereof.

Conventionally, Group III-V compound semiconductor laser diodes such as AlGaAs infrared laser diodes or AlInGaP red laser diodes have been widely used as laser diodes for communications and as read/write elements for CDs (Compact Discs) or DVDs (Digital Versatile Discs).

Furthermore, in recent years, semiconductor laser diodes, which can output blue light and ultraviolet light having smaller wavelengths, have been implemented with the use of Group III nitride semiconductors represented by AlₓGa_{z}In_{1-x-z}N (where 0≦x≦1, 0≦z≦1, and 0≦1-x-z≦1). For example, Group III nitride semiconductor laser diodes have been put into practical use as light sources for read/write operations of high-density optical disks such as Blu-ray Discs (Blu-ray Disc is a registered trademark). Currently, blue laser diodes with a low output of tens mW for reproduction, and high-output laser diodes of as high as 100 mW for record are available on the market. A further increase in output power for improving a recording rate is demanded, and laser diodes of as high as 200 mW are now hitting the market.

Traditionally, when manufacturing a light-emitting device using a Group III nitride semiconductor, a sapphire (single crystal alumina) substrate was primarily used. However, there is an extremely large lattice mismatch of about 13% between the sapphire substrate and the Group III nitride semiconductor formed on the substrate. Thus, the nitride semiconductor grown on the sapphire substrate includes a high density of defects such as dislocations. This makes it difficult to obtain a high-quality Group III nitride semiconductor.

Recently, to address this problem, nitride gallium (GaN) substrates with a low defect density have been developed, and methods of utilizing GaN substrates have been actively researched and developed. GaN substrates are proposed primarily for use as substrates for semiconductor laser diodes.

When a Group III nitride semiconductor is grown on a GaN substrate, on the C plane of the crystal, i.e., a (0001) plane of a plane orientation, there is a problem that excellent flatness and crystallinity cannot be obtained on the surface of the grown Group III nitride semiconductor. To tackle this problem, Patent Document 1 suggests a technique for reducing lattice defects of a semiconductor layer formed on the upper surface of a semiconductor light-emitting layer which is formed on a GaN substrate by tilting the upper surface of the GaN substrate at an angle from 0.03° to 10° with respect to the C plane to extend the lifetime of a light emitting element.

Furthermore, in view of improving the flatness of the surface of a grown semiconductor layer, Patent Documents 2 and 3 respectively show as useful substrates, a GaN substrate having an upper surface oriented at an angle ranging from 0.1° to 1.0° in the <1-100> direction of the crystal axis with respect to the C plane, and a GaN substrate oriented at an angle ranging from 0.3° to 0.7°. For simplicity, in the present description, the minus signs (“−”), which are associated with indexes in the plane orientation and the crystal axis, represent the inversions of the indexes following the minus signs.

Moreover, Patent Document 4 teaches using as a cladding layer, a superlattice layer, which is formed by stacking Group III nitride semiconductors having different compositions, on a buffer layer of n-type GaN. The single layer has a film thickness less than an elastic critical thickness. This significantly improves the crystallinity. Therefore, an extremely flat film having excellent crystallinity without any crack can be formed to dramatically extend the life time of a laser diode.

### [References]

### [Patent Documents]

[Patent Document 1] Japanese Published Patent Application 2000-223743
[Patent Document 2] Japanese Published Patent Application 2006-156958
[Patent Document 3] Japanese Published Patent Application 2004-327655
[Patent Document 4] Japanese Published Patent Application 2002-261014

### SUMMARY

When forming a semiconductor laser diode using a GaN substrate, not only the crystallinity of a Group III nitride semiconductor layer formed on the GaN substrate, but also the flatness of the surface of the Group III nitride semiconductor layer are desired.

This is because, low flatness causes scattering of light, and the scattered light is multiply reflected in the longitudinal direction of a laser cavity to interfere with primary laser light so that a far field pattern (FFP) in a vertical direction to the main surface of the substrate deviates from a Gaussian shape, and the scattered light oozes out from a cladding layer to cause a ripple. Using laser light having such a distorted vertical FFP in an optical disk system is not preferable, since a decrease in the use efficiency of light causes noise, a reading error and the like.

After various studies, the present inventors confirmed that flatness, which is obtained only by limiting the range of the tilt angles of a substrate, is not sufficient in a semiconductor laser diode including a buffer layer of GaN as suggested in the above-referenced Patent Documents 1-4.

In view of the above-described problems, the present invention aims to form on a GaN substrate, a Group III nitride semiconductor layer with excellent flatness and crystallinity, and to obtain a vertical FFP close to a Gaussian shape.

To achieve the objectives, a first nitride semiconductor laser diode according to the present invention includes a substrate of n-type GaN; and a multilayer structure including an n-type cladding layer of AlₓGa₁₋ₓN (where 0<x<1) formed on and in contact with a main surface of the substrate, an active layer formed on the n-type cladding layer, and a p-type cladding layer formed on the active layer. The main surface of the substrate is oriented at an angle ranging from 0.35° to 0.7° with respect to a (0001) plane of a plane orientation. The composition x of the AlₓGa₁₋ₓN is in a range from 0.025 to 0.04.

According to the first nitride semiconductor laser diode, a multilayer structure having a flat surface can be implemented to obtain a vertical FFP having an excellent shape close to a Gaussian shape. Furthermore, since the composition x of the AlₓGa₁₋ₓN is in the range from 0.025 to 0.04, laser light can be readily confined in the multilayer structure to prevent oozing out of the light to the substrate. Moreover, no crack occurs between the multilayer structure and the substrate due to lattice distortion. This enables implementation of a nitride semiconductor laser diode having a low operating voltage and an excellent vertical FFP. Furthermore, the multilayer structure can obtain an excellent vertical FFP even with a minimum film thickness. This improves the reliability and lowers the manufacturing cost.

In the first nitride semiconductor laser diode, a root mean square (RMS) value of surface roughness showing surface flatness of the multilayer structure is preferably 3 nm or less.

In the first nitride semiconductor laser diode, the main surface of the substrate may be oriented in a <11-20> direction of a crystal axis with respect to the (0001) plane.

This prevents a tilt of facets of a cavity to minimize mirror damage.

A second nitride semiconductor laser diode according to the present invention includes a substrate of n-type GaN; and a multilayer structure including an n-type cladding layer of AlₓGa₁₋ₓN (where 0<x<1) formed on and in contact with a main surface of the substrate, and an active layer formed on the n-type cladding layer, and a p-type cladding layer formed on the active layer. The main surface of the substrate is oriented at an angle ranging from 0.25° to 0.7° with respect to a (0001) plane of a plane orientation. The substrate is formed by alternately stacking layers of high and low impurity concentrations in a depth direction of the main surface. The composition x of the AlₓGa₁₋ₓN is in a range from 0.025 to 0.04.

With the use of the second nitride semiconductor laser diode, a multilayer structure having a flatter surface can be implemented, since the substrate is formed by alternately stacking the layers of high and low impurity concentrations in the depth direction of the main surface, and wavelength fluctuations (e.g., non-uniformity of the indium (In) composition) in the active layer can be suppressed to reduce a non-uniform current injection and prevent damage to a guided wave. This enables implementation of a nitride semiconductor laser diode having a low operating current and an excellent vertical FFP.

In the second nitride semiconductor laser diode, the impurity may be at least one element selected from the group consisting of silicon, germanium, oxygen, sulfur, and selenium.

In the second nitride semiconductor laser diode, a root mean square (RMS) value of surface roughness showing surface flatness of the multilayer structure is preferably 3 nm or less.

In the second nitride semiconductor laser diode, the main surface of the substrate may be oriented in a <11-20> direction of a crystal axis with respect to the (0001) plane.

A method of manufacturing a nitride semiconductor laser diode according to the present invention includes performing heat treatment to a main surface of a substrate of n-type GaN which is oriented at an angle ranging from 0.35° to 0.7° with respect to a (0001) plane of a plane orientation, raising a temperature to a temperature 100° C. or more higher than a heating temperature of the heat treatment, forming a first n-type cladding layer of AlₓGa₁₋ₓN (where 0<x<1) on the main surface of the substrate after the temperature raising, and forming a multilayer structure by sequentially forming an active layer and a p-type cladding layer on the formed first cladding layer. The temperature raising includes forming a second n-type cladding layer of Al_{y}Ga_{1-y}N (where 0<y<1 and y<x) on and in contact with the main surface of the substrate. The composition x of the AlₓGa₁₋ₓN is in a range from 0.025 to 0.04.

According to the method of manufacturing a nitride semiconductor laser diode of the present invention, the temperature rising includes forming the second n-type cladding layer of Al_{y}Ga_{1-y}N (where 0<y<1 and y<x) on and in contact with the main surface of the substrate. Thus, the flatness of the main surface of the substrate obtained in the temperature raising is hardly degraded. This enables formation of a multilayer structure having a flat surface with excellent reproducibility to implement a nitride semiconductor laser diode having an excellent vertical FFP. Furthermore, since the composition x of the AlₓGa₁₋ₓN is in the range from 0.025 to 0.04, laser light can be readily confined in the multilayer structure to prevent oozing out of the light to the substrate. Moreover, no crack occurs between the multilayer structure and the substrate due to lattice distortion. This enables implementation of a nitride semiconductor laser diode having a low operating voltage and an excellent vertical FFP. Furthermore, the multilayer structure can obtain an excellent vertical FFP even with a minimum film thickness. This improves the reliability and lowers the manufacturing cost.

As described above, according to the nitride semiconductor laser diode of the present invention and the manufacturing method thereof, the flatness of the multilayer structure including Group III nitride semiconductors formed on the substrate of nitride gallium (GaN) is improved to prevent scattering of light, thereby obtaining an excellent FFP in the vertical direction to the substrate. Moreover, the flatness of the multilayer structure is improved to suppress non-uniformity of the indium (In) composition in the active layer, thereby preventing damage to a guided wave of laser light. As a result, a flat crystal can be obtained in a wide area, even when a substrate has a large tilt angle distribution in the substrate surface, thereby improving the manufacturing yield.

### BRIEF DESCRIPTION OF THE DRAWINGS

FIG. 1 is a cross-sectional view illustrating a nitride semiconductor laser diode according to the first example embodiment.

FIG. 2 is a cross-sectional view illustrating a nitride semiconductor laser diode according to the comparative example.

FIG. 3 is a graph illustrating the relationship between the tilt angle and the surface roughness of an n-type GaN substrate and an n-type cladding layer (AlGaN) in the nitride semiconductor laser diode of the first example embodiment, along with the comparative example.

FIG. 4 is a graph illustrating the relationship between the surface roughness and the distortion amount of a vertical FFP of a multilayer structure including a laser structure.

FIG. 5 is a cross-sectional view illustrating a nitride semiconductor laser diode according to the second example embodiment.

FIG. 6 is a graph illustrating the relationship between the tilt angle and the surface roughness of an n-type GaN substrate and an n-type cladding layer (AlGaN) in an example nitride semiconductor laser diode in accordance with the first example embodiment, the second example embodiment, and the comparative example.

### DETAILED DESCRIPTION

### First Example Embodiment

A first example embodiment is described with reference to the drawings. Note that the following example embodiments are mere examples, and the present invention is not limited to these example embodiments.

As shown in FIG. 1, a nitride semiconductor laser diode according to the first example embodiment has a multilayer structure 120, which includes a plurality of Group III nitride semiconductors formed by epitaxial growth, on a main surface of a substrate 101 of, for example, n-type nitride gallium (GaN).

The multilayer structure 120 includes an n-type cladding layer 102 of n-type AlₓGa₁₋ₓN (where 0<x<1), an n-type guide layer 103 of n-type GaN, a multiple quantum well (MQW) active layer 104 of InGaN, a p-type guide layer 105 of p-type GaN, a p-type carrier block layer 106 of p-type AlGaN, a p-type cladding layer 107 having a superlattice structure of p-type AlGaN and p-type of GaN, and a p-type contact layer 108 of p-type GaN, which are formed sequentially on the substrate 101.

The p-type cladding layer 107 and a part of the p-type contact layer 108 are striped to form a ridge waveguide (a ridge stripe). A dielectric layer 109 of silicon dioxide (SiO₂) is formed on both sides and both side surfaces of the ridge stripe, i.e., both sides and both side surfaces of the ridge stripe of the p-type cladding layer 107 and both side surfaces of the p-type contact layer 108. A p-side electrode 110, which is in ohmic contact with the p-type contact layer 108, is formed on the p-type contact layer 108 exposed from the dielectric layer 109. Furthermore, a p-side pad electrode 111, which is coupled to the p-side electrode 110, is formed on the dielectric layer 109. An n-side electrode 112, which is in ohmic contact with the substrate 101, is formed on the surface (i.e., the back surface) of the substrate 101 which is on the opposite side to the surface provided with the n-type cladding layer 102.

Hereinafter, the detailed structure of the nitride semiconductor laser diode described above and a method of manufacturing the laser diode are explained.

First, for example, a substrate 101 of n-type GaN is prepared, which has a main surface oriented at 0.5° in a <11-20> direction of a crystal axis with respect to a (0001) plane (i.e., a C plane) of a plane orientation, and has a donor impurity at a concentration of about 1×10¹⁸cm⁻³.

Second, the above-described multilayer structure 120 is formed on the main surface of the prepared substrate 101 by, for example, a Metal Organic Chemical Vapor Deposition (MOCVD).

Before forming the multilayer structure 120, i.e., before growing the n-type cladding layer 102, the substrate 101 is heat-treated for ten minutes. Then, at a temperature of 1070° C., silicon (Si) is doped as a donor impurity at a concentration of 5×10¹⁷ cm⁻³ on the main surface of the substrate 101 to form the n-type cladding layer 102 of n-type Al_{0.03}Ga_{0.97}N with a thickness of 2.6 μm directly on the substrate 101 without interposing a buffer layer of GaN. Since a GaN crystal has a low equilibrium vapor pressure, even when the temperature is raised with ammonia (NH₃) gas being a Group V material supplied, nitrogen (N) is readily removed from the crystal to cause large surface roughness.

According to the studies of the present inventors, when the substrate 101 is heat-treated at a temperature from 500° C. to 970° C., the surface roughness after the ten-minute heat treatment is equivalent to the surface roughness before the heat treatment at a root mean square (RMS) value of 0.5 nm or less. However, when the heat treatment is performed at a relatively high temperature of 1050° C., a number of projections and recesses are formed in the surface, and the RMS value increases to 1.2 nm or more. On the other hand, when the substrate 101 is not heat-treated, the present inventors observed a high density hillock on the surface after being provided with the n-type semiconductor layers (the n-type cladding layer 102 and the n-type guide layer 103), and obtained a result indicating that three-dimensional growth occurs at an early stage of the crystal growth. From this result, it is found that at least heat treatment before forming a multilayer structure 120 is essential, and the heat treatment temperature needs to be set lower than a growth temperature of the n-type cladding layer 102, for example, at a temperature from 500° C. to 970° C. In general, it is preferable that a growth temperature of AlₓGa₁₋ₓN is higher than that of GaN, and as a growth condition of the n-type cladding layer 102 according to the first example embodiment, the temperature is preferably in a range from about 1070° C. to about 1150° C.

Furthermore, when the Al composition x of the AlₓGa₁₋ₓN is 0.1 or less with the crystal characteristics relatively close to those of GaN, as the Al composition x ranging from 0.025 to 0.04 of AlₓGa₁₋ₓN which forms the n-type cladding layer 102, it is known that the temperature for heat treatment to the substrate 101 is more preferably set within a range from 1070° C. to 1120° C. Thus, in the first example embodiment, the heat treatment temperature is set at 900° C., which is lower than the growth temperature of the n-type cladding layer 102, not to roughen the surface of the substrate 101 by the heat treatment; and then at an early stage of the growth of the n-type cladding layer 102, the n-type cladding layer 102 is grown from a composition y (e.g., y=0.025) in a low-temperature growth to a composition x (e.g., x=0.03) in a high-temperature growth when raising the heating temperature of the substrate 101 from 900° C. to 1070° C., thereby preventing deterioration of the surface flatness of the substrate 101 of n-type GaN which occurs in the heat treatment and the temperature raising. As a result, as described below, a multilayer structure 120 having a flat surface can be formed with excellent reproducibility.

The n-type cladding layer 102 is preferably thick to suppress a ripple occurring in the vertical FFP, which is caused by oozing out of light toward the substrate 101. However, GaN and AlₓGa₁₋ₓN (where x=0.03) have different lattice constants. Due to stress caused by the lattice mismatch, cracks occur when the film thickness of the AlₓGa₁₋ₓN exceeds a critical film thickness. Therefore, the composition and the film thickness of the n-type cladding layer 102 need to be set to appropriate values. In the n-type cladding layer 102, cracks occur due to an increase in stress caused by the lattice mismatch, and the stress varies with a change in an Al composition x and a film thickness w. Thus, the present inventors calculated stress contour lines based on the Al composition x and the film thickness w (μm) of the n-type cladding layer 102 to identify areas where a crack occurs and where it does not. The inventors' studies revealed that the relationship between the Al composition x and the film thickness w of the n-type cladding layer 102 preferably satisfy the following formula (1), and that, when using a multi-layer structure, the average composition of the multi-layer structure preferably satisfies the formula (1).

w<−350x+15.2 Formula (1)

Thus, to prevent occurrence of cracks in the n-type cladding layer 102, the maximum value of the Al composition x of the n-type cladding layer 102 is 0.043. However, being formed in contact with the substrate 101, the n-type cladding layer 102 also functions as a conventional buffer layer of GaN. It is known that the n-type cladding layer 102 needs to have a film thickness of 1 μm or more to alleviate the effects of defects caused at the interface with the substrate 101. Therefore, the maximum value of the Al composition x of the n-type cladding layer 102 is preferably 0.04.

Furthermore, the n-type cladding layer 102 needs to, as a minimum function of a cladding layer, limit oozing out of light toward the substrate 101 not to cause a ripple in the vertical FFP. Thus, the present inventors calculated contour lines of the possibility of oozing out of light causing a ripple based on the Al composition x and the film thickness w (μm) to identify areas where a ripple occurs and where it does not. The relationship between the Al composition x and the film thickness w preferably satisfy the following formula (2).

w>−30x+2.98 Formula (2)

The Al composition x is most preferably 0.01 or more in terms of limiting the total film thickness of the multilayer structure 120. Furthermore, as described above, in terms of preventing cracks in the n-type cladding layer 102 and preventing an increase in the operating voltage, the Al composition x is most preferably 0.04 or less. This composition enables minimization of the film thickness of the multilayer structure 120 and implementation of a nitride semiconductor laser diode having an excellent vertical FFP. This improves the reliability and lowers the manufacturing cost.

Then, on the n-type cladding layer 102 formed in the above-described manner, an n-type guide layer 103 of n-type GaN with a thickness of 100 nm, which is doped with silicon (Si) as a donor impurity at a concentration of 5×10¹⁷ cm⁻³. Next, an MQW active layer 104 having a triple quantum well of well layers of In_{0.10}Ga_{0.90}N with a thickness of 3 nm and barrier layers of In_{0.02}Ga_{0.98}N with a thickness of 7.5 nm, the p-type guide layer 105 of p-type GaN with a thickness of 120 nm, a p-type carrier block layer 106 of p-type Al_{0.2}Ga_{0.8}N with a thickness of 10 nm, a p-type cladding layer 107 with a superlattice (SL) structure of p-type Al_{0.03}Ga_{0.97}N/p-type GaN and the total film thickness of 0.5 μm, and a p-type contact layer 108 of p-type GaN with a thickness of 60 nm are formed sequentially on the n-type guide layer 103 to obtain a multilayer structure 120.

A growth temperature of the MQW active layer 104 during the growth is here set at about 800° C., and a growth temperature of the p-type cladding layer 107 during the growth is set at about 930° C. Each of the p-type carrier block layer 106 and the p-type cladding layer 107 is doped with magnesium (Mg) as an acceptor impurity at a concentration of 1×10¹⁹ cm⁻³, and the p-type contact layer 108 is doped with Mg at a concentration of 1×10²⁰ cm³.

Note that, as materials for an MOCVD method, for example, trimethyl gallium (TMG) as a Ga source, trimethyl aluminum (TMA) as an Al source, trimethyl indium (TMI) as an In source, and ammonia (NH₃) as a N source can be used. Furthermore, silane (SiH₄) gas can be used as a Si source which is a donor impurity, and bis(cyclopentadienyl)magnesium (Cp₂Mg) can be used as a Mg source which is an acceptor impurity.

Next, on the multilayer structure 120 including the crystal grown Group III nitride semiconductors, a SiO₂ film (not shown) with a thickness of 200 nm is deposited by, for example, a Chemical Vapor Deposition (CVD) method. Then, a stripe-shaped mask film for forming a ridge stripe is formed from the SiO₂ film by a lithography method and dry etching with Reactive Ion Etching (RIE). After that, with the use of the stripe-shaped mask film, the multilayer structure 120 is etched from the surface to a depth of about 0.5 μm by Inductively Coupled Plasma (ICP) dry etching with Cl₂ gas or SiCl₄ gas to form a ridge stripe extending in the <1-100> direction of the crystal axis. Then, the mask film is removed with a buffered hydrofluoric acid (BHF) solution.

Then, by the CVD method again, a dielectric layer 109 of SiO₂ with a thickness of 200 nm is deposited over the entire surface of the multilayer structure 120 provided with the ridge stripe. Then, an upper portion of the ridge stripe in the dielectric layer 109 is selectively opened by lithography and wet etching with a BHF solution.

Next, by for example, an electron beam evaporation method, a p-side electrode 110 of palladium (Pd)/platinum (Pt) is formed on the upper surface of the ridge stripe exposed from the dielectric layer 109, i.e., on the p-type contact layer 108. Then, by the electron beam evaporation method, a p-side pad electrode 111 for an interconnection made of titanium (Ti)/platinum (Pt)/gold (Au) is formed on the dielectric layer 109 to cover the p-side electrode 110.

Then, the substrate 101 is thinned to a thickness of 100 μm by polishing the back surface. After that, an n-side electrode 112 of Ti/Pt/Au is formed on the back surface of the thinned substrate 101 by, for example, the electron beam evaporation method.

Next, the substrate 101 in the wafer state is preliminarily cleaved in the vertical direction to the ridge stripe by scribing and breaking from the back surface of the substrate 101 to form cavity facets which face each other. Then, the front facet of the cavity facets is provided with a first multilayer dielectric reflection film having a reflectivity of about 18%. The rear facet is provided with a second multilayer dielectric reflection film having a reflectivity of about 95%. After that, the substrate 101 is secondarily cleaved in the vertical direction to the cleavage direction of the primary cleavage (in the direction parallel to the ridge stripe) to obtain a laser chip. Furthermore, the secondarily cleaved laser chip is mounted on and interconnected to a CAN package, thereby obtaining a nitride semiconductor laser diode.

As described above, in the first example embodiment, the main surface of the substrate 101 of n-type GaN has a tilt angle of 0.5° in the <11-20> axis direction with respect to the (0001) plane of the plane orientation. Furthermore, the n-type cladding layer 102 of n-type AlₓGa₁₋ₓN with the Al composition x of 0.03 and the film thickness of 2.6 μm is formed directly on the main surface of the substrate 101 without interposing a buffer layer of GaN. This improves the flatness of the n-type cladding layer 102 and the n-type guide layer 103. As a result, the semiconductor laser diode according to this example embodiment, which has a laser structure formed on the n-type guide layer 103 with a flat upper surface, has an excellent vertical FFP almost identical to a Gaussian shape.

The present inventors carefully investigated the cause of distortion of the vertical FFP, which is raised as a problem to be addressed by the present invention. After various studies, the present inventors found that the cause is that light propagating inside a waveguide is scattered outside the waveguide due to the surface morphology of a semiconductor layer. To be specific, scattered light, which is caused by fine projections and recesses existing in the surface of the semiconductor layer at an interval ranging from some μm to tens of μm, is multiply reflected in the longitudinal direction of a cavity, and interferes with primary laser light so that the vertical FFP deviates from a Gaussian shape.

Furthermore, light, which oozes outside the n-type cladding layer 102 due to scattering, propagates inside the substrate 101 of n-type GaN, which has a higher refractive index than the n-type cladding layer 102 and is transparent to an oscillation wavelength, thereby causing a ripple on the substrate 101 side of the vertical FFP. Note that no ripple occurs on the p-type semiconductor side of the vertical FFP, since the scattered light oozing to the p-type semiconductor side is absorbed by the p-side electrode 110 and the p-side pad electrode 111.

### COMPARATIVE EXAMPLE

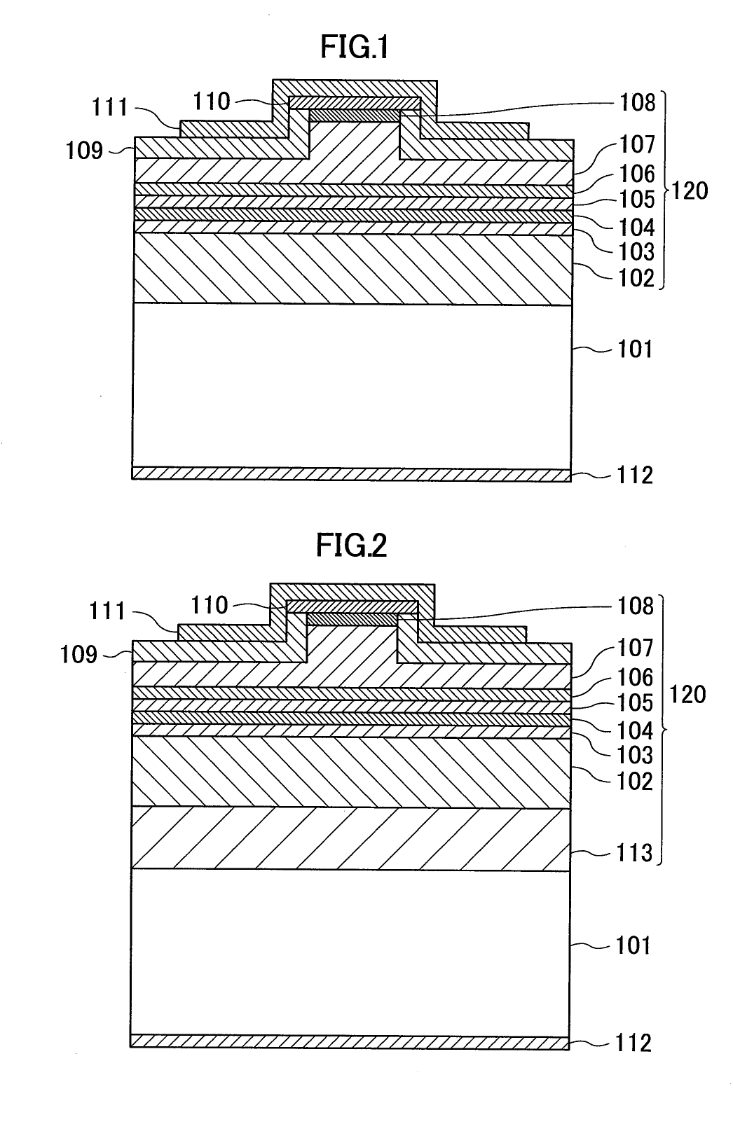

Hereinafter, a comparative example of the nitride semiconductor laser diode according to the first example embodiment is described with reference to FIG. 2. A method of manufacturing the nitride semiconductor laser diode according to the comparative example is described herein together with the structure of the nitride semiconductor laser diode.

First, as shown in FIG. 2, a substrate 101 of n-type GaN is prepared, which is equivalent to that in the first example embodiment, i.e., which has a main surface oriented at 0.5° in the <11-20> axis direction with respect to the (0001) plane of the plane orientation, and has a donor impurity at a concentration of about 1×10¹⁸ cm⁻³.

Next, the substrate 101 is heat-treated for ten minutes at a temperature of 900° C. Then, an n-type buffer layer 113 of n-type GaN with a thickness of 2.6 μm which is doped with Si as a donor impurity at a concentration of 5×10¹⁷ cm⁻³, and an n-type cladding layer 102 of n-type Al_{0.03}Ga_{0.97} N with a thickness of 2.6 μm which is doped with Si as a donor impurity at a concentration of 5×10¹⁷cm⁻³ are formed sequentially on the main surface of the substrate 101.

After that, similar to the first example embodiment, an n-type guide layer 103, an MQW active layer 104 of a triple quantum well, the p-type guide layer 105, a p-type carrier block layer 106, a p-type cladding layer 107, and a p-type contact layer 108 are formed sequentially on the n-type cladding layer 102 by epitaxial growth. Then, a ridge stripe is provided to form a dielectric layer 109, a p-side electrode 110, a p-side pad electrode 111, and an n-side electrode 112. Next, the substrate 101 in the wafer state is primarily and secondarily cleaved to be mounted on and interconnected to a CAN package, thereby obtaining the nitride semiconductor laser diode according to the comparative example.

As described above, in this comparative example, the n-type buffer layer 113 of n-type GaN with the film thickness of 2.6 μm, and the n-type cladding layer 102 of n-type AlₓGa₁₋ₓN with the Al composition x of 0.03 and the film thickness of 2.6 μm are formed on the substrate 101 of n-type GaN, which has the main surface oriented at 0.5° in the <11-20> axis direction with respect to the (0001) plane of the plane orientation.

In this comparative example, the n-type buffer layer 113, the n-type cladding layer 102, and the n-type guide layer 103, which are n-type semiconductor layers; have lower flatness than those in the first example embodiment. As a result, the semiconductor laser diode according to this comparative example has a vertical FFP deviating from a Gaussian shape. Furthermore, a ripple occurs in the vertical FFP.

FIG. 3 illustrates the relationship between the tilt angle of the main surface of the substrate 101 of n-type GaN (generally called an “off-angle” of a substrate) and the surface roughness of the upper surface of an n-type semiconductor layer formed directly on the main surface. As representatives of n-type semiconductor layers, a GaN layer with a thickness of 2.6 μm (the comparative example) and an Al_{0.03}Ga_{0.97}N layer with a thickness of 2.6 μm (the first example embodiment) are compared. In FIG. 3, symbols ♦ denote the states of the GaN layer, and symbols ◯ denote the states of the Al_{0.03}Ga_{0.97}N layer. The vertical axis of FIG. 3 represents RMS values of surface roughness showing the surface flatness of the GaN layer and the Al_{0.03}Ga_{0.97}N layer, where the surfaces are observed in an about 300 μm square using a Scanning White-Light Interference Microscope (Zygo Corporation). Projections and recesses existing at an interval from some μm to tens μm are observed here. Furthermore, the RMS values of surface roughness show characteristics not only when the Al composition x of the AlₓGa₁₋ₓN layer is 0.03 but when it is between 0.025 and 0.04. In each of the first example embodiment and the comparative example, the RMS value reaches the minimum value when the tilt angle is in a range from 0.4° to 0.5°, and the semiconductor layer has excellent surface morphology. When the tilt angle is less than 0.4° and over 0.5°, the RMS value gradually increases.

What is to be noted is that, when using the Al_{0.03}Ga_{0.97}N layer according to the first example embodiment, the RMS value is at almost any tilt angle, 3 nm or less, i.e., smaller than the value when using the GaN layer of the comparative example. Furthermore, the Al_{0.03}Ga_{0.97}N layer is less dependent on the tilt angle of the substrate 101, and there is no significant difference between the RMS values when the tilt angle is in a range from 0.35° to 0.7°. That is, it is found that, when the tilt angle is in a range from 0.35° to 0.7°, the Al_{0.03}Ga_{0.97}N layer has higher flatness than the GaN layer at any tilt angle.

Moreover, the present inventors obtained a similar result when the Al composition x is in a range from 0.025 to 0.04. When the Al composition x is in a range from 0.025 to 0.04, the Al_{0.03}Ga_{0.97}N layer has RMS values less than half of those of the GaN layer. Therefore, a flat n-type semiconductor layer with excellent surface morphology can be obtained in a wide range of the tilt angles.

Regarding the tilt direction of the substrate 101, a similarly good result is obtained in each of the <1-100> direction and the <11-20> direction of the crystal axis. No difference is observed in any other crystal axis direction.

In general, as shown in this comparative example, the n-type buffer layer 113 of n-type GaN is formed between the substrate 101 of n-type GaN and the n-type cladding layer 102 to alleviate stress caused by the difference in lattice constants between the substrate 101 and the n-type cladding layer 102. However, the above comparison result indicates that the flatness is degraded by providing the n-type buffer layer 113 of n-type GaN between the substrate 101 of n-type GaN and the n-type cladding layer 102 of n-type AlₓGa₁₋ₓN.

In the first example embodiment, since the n-type cladding layer 102 of n-type AlₓGa₁₋ₓN with the Al composition x of 0.03 is directly formed on the main surface of the substrate 101 of n-type GaN, there is no need to increase the film thickness more than necessary as an n-type semiconductor layer. In the MQW active layer 104 formed on the upper surface of the n-type cladding layer 102, and the p-type semiconductor layers on the active layer, the state of the crystal surface of the n-type semiconductor layer is maintained almost perfectly. Therefore, the improvement in the flatness of the n-type cladding layer 102 leads to an improvement in the characteristics of a nitride semiconductor laser diode.

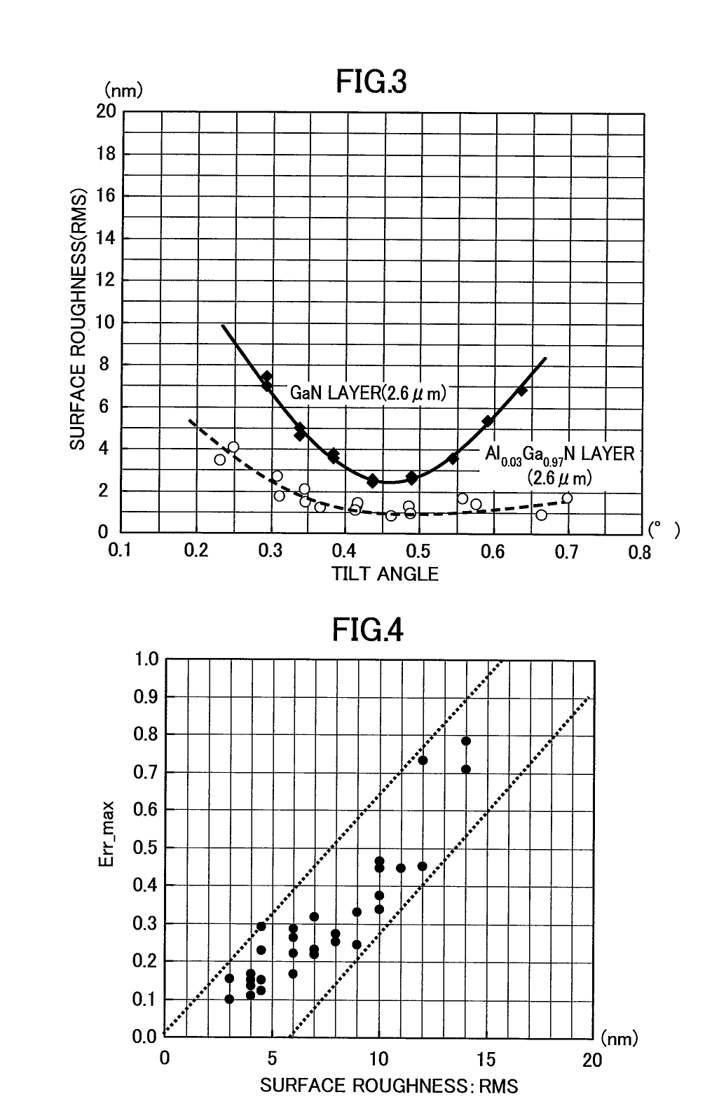

FIG. 4 illustrates the relationship between the RMS value of surface roughness showing the surface flatness, and the distortion amount of the vertical FFP. As an index of the distortion amount of the vertical FFP, the maximum value (Err_Max) of the difference between an ideal Gaussian waveform and the measured value of the vertical FFP of a nitride semiconductor laser diode is used. There is a correlation between the RMS value and the distortion amount of the vertical FFP. When the RMS value is 3 nm or less, the Err_Max is stable at 0.2 or less. This prevents occurrence of noise during an operation of an optical disk system and occurrence of a reading error. This shows that the RMS value is appropriate as the index showing the distortion amount of the vertical FFP. The vertical FFP is improved by reducing projections and recesses of the crystal surface occurring in the n-type cladding layer 102.

### Second Example Embodiment

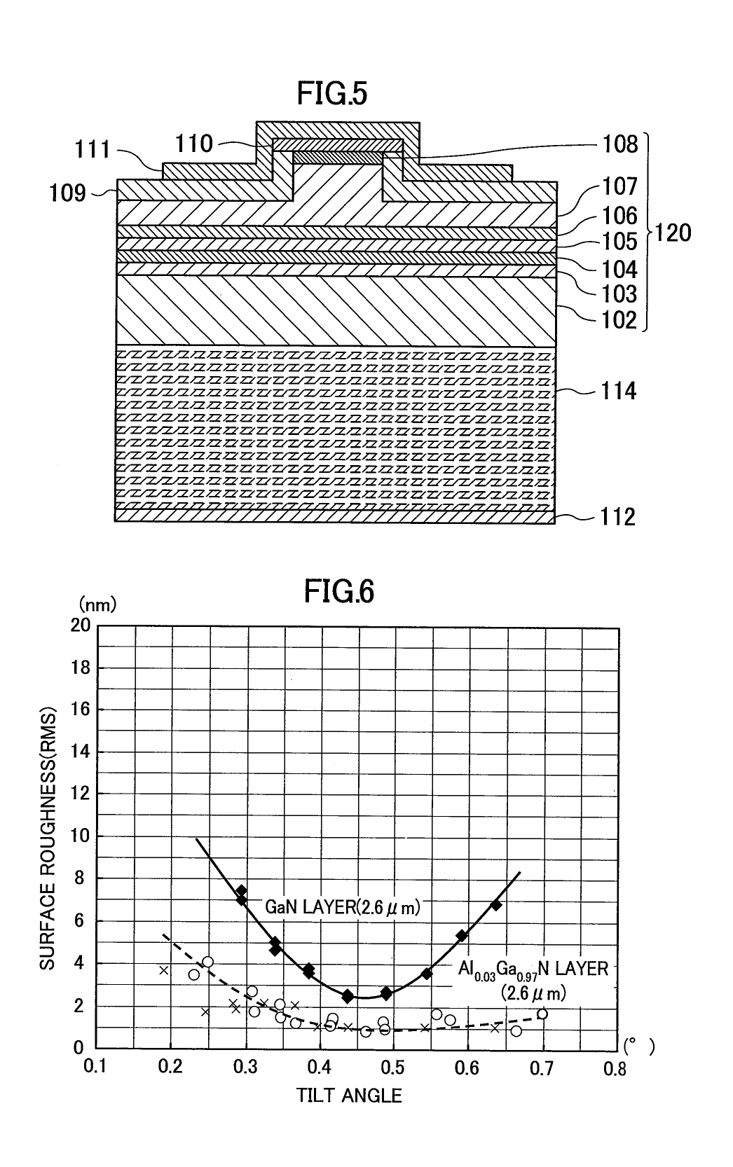

Hereinafter, a nitride semiconductor laser diode according to the second example embodiment is described with reference to FIG. 5. A method of manufacturing the nitride semiconductor laser diode according to the second example embodiment is described herein together with the structure of the nitride semiconductor laser diode.

First, as shown in FIG. 5, a substrate 114 of n-type GaN is prepared, which has a main surface oriented at about 0.4° in a <11-20> axis direction with respect to a (0001) plane of a plane orientation, and has a donor impurity at an average concentration of about 1×10¹⁸ cm⁻³. The substrate 114 prepared in the second example embodiment is formed by alternately stacking layers of high and low donor impurity concentrations in a thickness direction of the substrate 114. That is, the substrate 114 is formed so that the impurity concentration of the donor varies periodically. Silicon (Si) can be used here as the donor impurity.

Next, the substrate 114 is heat-treated for ten minutes. The heat treatment temperature is here set at 950° C. not to roughen the surface of the substrate 114 by the heat treatment.

Then, an n-type cladding layer 102 of Al_{0.03}Ga_{0.97}N is grown on the main surface of the heat-treated substrate 114 without forming an n-type buffer layer of n-type GaN. At an early stage of the growth of the n-type cladding layer 102, the n-type cladding layer 102 is grown while raising the temperature from 950° C. to 1070° C. to prevent deterioration of the flatness of the substrate 114 of n-type GaN which occurs in the heat treatment and the temperature raising. This enables formation of a multilayer structure 120 having a flat surface. As a result, a nitride semiconductor laser diode can be manufactured with excellent reproducibility.

Note that, also in the second example embodiment, the n-type cladding layer 102 is grown in the temperature raising from 950° C. to 1070° C., while changing the Al composition from 0.025 to 0.03.

After that, similar to the first example embodiment, an n-type guide layer 103, an MQW active layer 104 of a triple quantum well, a p-type guide layer 105, a p-type carrier block layer 106, a p-type cladding layer 107, and a p-type contact layer 108 are formed sequentially on the n-type cladding layer 102 by epitaxial growth. Then, a ridge stripe is provided to form a dielectric layer 109, a p-side electrode 110, a p-side pad electrode 111, and an n-side electrode 112. Next, the substrate 114 in the wafer state is primarily and secondarily cleaved to be mounted on and interconnected to an CAN package, thereby obtaining a nitride semiconductor laser diode according to the second example embodiment.

In the first example embodiment, the n-type cladding layer 102 of n-type AlₓGa₁₋ₓN is directly formed on the substrate 101. This improves the flatness of the n-type semiconductor layer, and as a result, the vertical FFP of a semiconductor laser diode formed on the n-type semiconductor layer is improved.

In the second example embodiment, the substrate 114 of n-type GaN is formed so that the layers of high and low donor impurity concentrations are stacked alternately in the thickness direction of the substrate 114. Note that, when the donor impurity concentration is lower than 1×10¹⁷ cm⁻³ at a certain depth of the substrate 114, an increase in resistivity in the crystal raises the operating voltage. Therefore, in the substrate 114, the minimum value of the donor impurity concentration at a certain depth needs to be set at 1×10¹⁷ cm⁻³ or more.

The substrate 114 can hardly be formed by a pulling method out of a liquid phase as used for forming a substrate of silicon (Si), gallium arsenide (GaAS), or indium phosphide (InP), since a GaN crystal has a low equilibrium vapor pressure. Thus, vapor phase epitaxy is primarily used for forming the substrate 114. As the vapor phase epitaxy, heteroepitaxial growth is generally performed by Metal Organic Chemical Vapor Deposition used in each of the example embodiments or Hydride Vapor Phase Epitaxy (HVPE) having a higher growth rate using sapphire or GaAx as the seed substrate.

Conventionally, in such heteroepitaxial growth, a superlattice structure is often used for improving the flatness of the substrate. The use of a superlattice structure alleviates stress caused by a lattice mismatch and improves the crystallinity, thereby improving the flatness.

On the other hand, unlike the method using a superlattice structure, epitaxial growth by vapor phase epitaxy prevents occurrence of abnormal growth due to three-dimensional cell growth and enables step-flow growth (two-dimensional growth) by decreasing the impurity concentration in the vapor phase epitaxy. This enables formation of a substrate having a flat surface. Particularly, when the off-angle is small, the flatness of the substrate can be largely improved, since a large terrace width is achieved by preventing occurrence of abnormal growth. By contrast, in a conventional substrate of GaN with a uniform impurity concentration, the resistivity is raised by decreasing the donor impurity concentration. Thus, it is not preferable to form a substrate in which only the donor impurity concentration is lowered, since it leads to a rise in the operating voltage of a laser diode.

The present inventors found it possible to form a substrate 114 of n-type GaN having a main surface with improved flatness and being capable of preventing a rise in the resistivity by alternately stacking layers of high and low donor impurity concentrations in the thickness direction of the substrate.

Similar to FIG. 3, FIG. 6 illustrates the relationship between the tilt angle of the main surface of the substrate 114 of GaN and the surface roughness of the upper surface of the n-type semiconductor layer formed directly on the main surface.

As shown in FIG. 6, in the second example embodiment, when using the substrate 114 including layers of high and low donor impurity concentrations stacked alternately in the thickness direction of the substrate; the RMS value reaches the minimum value when the tilt angle is in a range from 0.4° to 0.5°, and the semiconductor layer has excellent surface morphology. This phenomenon is equivalent to the phenomena in the first example embodiment and the comparative example. However, it is apparent from FIG. 6 that the crystallinity is improved also in an area where the substrate 114 has a small off-angle, for example, where the tilt angle is 0.25°. As a result, even on a substrate having a small tilt angle, the flatness of the n-type semiconductor layer can be improved. In FIG. 6, symbols ♦ denote the states of the GaN layer, symbols ◯ denote the states of the Al_{0.03}Ga_{0.97}N layer (on the substrate 101), and symbols × denote the states of the Al_{0.03}Ga_{0.97}N layer (on the substrate 114).

As such, the substrate 114, which is formed by alternately stacking layers of high and low donor impurity concentrations in the thickness direction, is less dependent on the tilt angle than in the first example embodiment, particularly in the area where the tilt angle is small. To be specific, there is no significant difference between the RMS values when the tilt angle of the substrate 114 is in a range from 0.25° to 0.7°. Thus, it can be seen that, when the tilt angle is in a range from 0.25° to 0.7°, the Al_{0.03}Ga_{0.97}N layer on the substrate 114 has higher flatness than the GaN layer directly formed on a substrate of GaN at any case. The Al_{0.03}Ga_{0.97}N layer has here RMS values less than half of those of the GaN layer, and therefore, a flat n-type semiconductor layer with excellent surface morphology can be obtained in a wide range of the tilt angles.

Regarding the tilt direction of the substrate 114, a similarly good result is obtained in each of the <1-100> direction and the <11-20> direction of the crystal axis. No difference is observed in any other crystal axis direction.

As in the second example embodiment, by alternately stacking layers of high and low donor impurity concentrations in the thickness direction of the substrate 114 of n-type GaN, deterioration of the surface flatness of the substrate 114 occurring in the heat treatment and the temperature raising can be prevented, even in an area where the substrate 114 has a small tilt angle. Thus, the n-type cladding layer 102 having a flat surface can be formed with excellent reproducibility. This further improves the vertical FFP of the semiconductor laser diode according to the second example embodiment which is formed on the n-type cladding layer 102.

As such, the difference in the donor impurity concentration provided inside the substrate 114 serves the function of improving the surface flatness of the substrate 114. Therefore, the difference in the donor impurity concentration may be formed only near the surface of the substrate 114, or entirely in the depth direction of the substrate 114.

Furthermore, the impurity added to the substrate 114 is not limited to silicon (Si) as described in the second example embodiment, and should contain at least one element selected from the group consisting of germanium (Ge), oxygen (O), sulfur (S) and selenium (Se).

Moreover, the donor impurity contained in the substrate 114 and the donor impurities contained in the n-type cladding layer 102 and the n-type guide layer 103 are not necessarily the same, and may differ from each other.

As described above, according to the second example embodiment, a nitride semiconductor laser diode having an excellent vertical FFP can be implemented, since the multilayer structure 120 forming the nitride semiconductor laser diode has a flatter surface.

Moreover, since wavelength fluctuations (e.g., non-uniformity of the indium (In) composition) in the MQW active layer 104 can be suppressed to reduce a non-uniform current injection and prevent damage to a guided wave. This reduces the threshold current and the operating current, and improves the slope efficiency to largely improve the optical characteristics, thereby achieving a longer life time of a nitride semiconductor high output laser diode.

As described above, the nitride semiconductor laser diode according to the present disclosure has an excellent vertical FFP, since the flatness of the multilayer structure having a laser structure including the Group III nitride semiconductors is improved to prevent scattering of light; and is thus useful as a semiconductor laser diode formed on a substrate of GaN and a manufacturing method thereof.

What is claimed is:

1. A nitride semiconductor laser diode comprising:
a substrate of n-type GaN; and
a multilayer structure including an n-type cladding layer of AlₓGa₁₋ₓN (where 0<x<1) formed on and in contact with a main surface of the substrate, an active layer formed on the n-type cladding layer, and a p-type cladding layer formed on the active layer, wherein
the main surface of the substrate is oriented at an angle ranging from 0.35° to 0.7° with respect to a (0001) plane of a plane orientation, and
the composition x of the AlₓGa₁₋ₓN is in a range from 0.025 to 0.04.

2. The nitride semiconductor laser diode of claim 1, wherein a root mean square (RMS) value of surface roughness showing surface flatness of the multilayer structure is 3 nm or less.

3. The nitride semiconductor laser diode of claim 1, wherein the main surface of the substrate is oriented in a <11-20> direction of a crystal axis with respect to the (0001) plane.

4. A nitride semiconductor laser diode comprising:
a substrate of n-type GaN; and
a multilayer structure including an n-type cladding layer of AlₓGa₁₋ₓN (where 0<x<1) formed on and in contact with a main surface of the substrate, and an active layer formed on the n-type cladding layer, and a p-type cladding layer formed on the active layer, wherein
the main surface of the substrate is oriented at an angle ranging from 0.25° to 0.7° with respect to a (0001) plane of a plane orientation,
the substrate is formed by alternately stacking layers of high and low impurity concentrations in a depth direction of the main surface, and
the composition x of the AlₓGa₁₋ₓN is in a range from 0.025 to 0.04.

5. The nitride semiconductor laser diode of claim 4, wherein the impurity is at least one element selected from the group consisting of silicon, germanium, oxygen, sulfur, and selenium.

6. The nitride semiconductor laser diode of claim 4, wherein a root mean square (RMS) value of surface roughness showing surface flatness of the multilayer structure is 3 nm or less.

7. The nitride semiconductor laser diode of claim 4, wherein the main surface of the substrate is oriented in a <11-20> direction of a crystal axis with respect to the (0001) plane.

8. A method of manufacturing a nitride semiconductor laser diode comprising:
performing heat treatment to a main surface of a substrate of n-type GaN which is oriented at an angle ranging from 0.35° to 0.7° with respect to a (0001) plane of a plane orientation;
raising a temperature to a temperature 100° C. or more higher than a heating temperature of the heat treatment;
forming a first n-type cladding layer of AlₓGa₁₋ₓN (where 0<x<1) on the main surface of the substrate after the temperature raising;
forming a multilayer structure by sequentially forming an active layer and a p-type cladding layer on the formed first cladding layer, wherein
the temperature raising includes forming a second n-type cladding layer of Al_{y}Ga_{1-y}N (where 0<y<1 and y<x) on and in contact with the main surface of the substrate, and
the composition x of the AlₓGa₁₋ₓN is in a range from 0.025 to 0.04.
